(19) United States
(12) Patent Application Publication
(10) Pub. No.: US 2024/0006496 A1
(43) Pub. Date: Jan. 4, 2024

(54) SEMICONDUCTOR DEVICE WITH ROBUST INNER SPACER

(71) Applicant: International Business Machines Corporation, Armonk, NY (US)

(72) Inventors: Shogo Mochizuki, Mechanicville, NY (US); Juntao Li, Cohoes, NY (US); Kangguo Cheng, Schenectady, NY (US)

(21) Appl. No.: 17/809,959

(22) Filed: Jun. 30, 2022

(51) Int. Cl. H01L 29/417; H01L 29/06; H01L 29/08; H01L 29/423; H01L 29/786; H01L 29/775; H01L 21/02; H01L 29/66

(52) U.S. Cl. CPC H01L 29/41775; H01L 29/0673; H01L 29/0847; H01L 29/42392; H01L 29/78696; H01L 29/775; H01L 21/02603; H01L 21/02532; H01L 29/66545; H01L 29/66553; H01L 29/66742; H01L 29/66439

(57) ABSTRACT

A semiconductor structure includes a plurality of semiconductor layers vertically stacked over a semiconductor substrate. Each of the plurality of semiconductor layers defining a channel region of the semiconductor structure. A source/drain region is located on opposite ends of the plurality of semiconductor layers while a metal gate stack surrounds each of the plurality of semiconductor layers. An inner spacer having a concave surface curving inward in a direction towards the source/drain region is located between each of the plurality of semiconductor layers for separating the metal gate stack from the source/drain region.

### BACKGROUND

The present invention generally relates to the field of complementary metal-oxide semiconductor (CMOS) devices, and more particularly to nanosheet field effect transistor devices.

In contemporary semiconductor device fabrication processes a large number of semiconductor devices, such as field effect transistors (FETs), are fabricated on a single wafer. Some non-planar device architectures, including nanosheet FETs, provide increased device density and increased performance over planar devices. In nanosheet FETs, in contrast to conventional FETs, the gate stack wraps around the full perimeter of each nanosheet, enabling fuller depletion in the channel region, and reducing short-channel effects. The wrap-around gate structures used in nanosheet devices also enable greater management of leakage current in the active regions, even as drive currents increase.

Nanosheet FETs often include thin alternating layers (nanosheets) of different semiconductor materials arranged in a stack. Typically, nanosheets are patterned into nanosheet fins. Once the nanosheet fins are patterned, a dummy gate is formed over a channel region of the nanosheet fins, and source/drain regions are formed adjacent to the dummy gate. In some devices, once the dummy gate and the source/drain regions have been formed, an etching process is performed to selectively remove nanosheet layers of one of the dissimilar materials from the fins. The etching process results in the undercutting and suspension of the layers of the nanosheet fin to form nanosheets or nanowires. The nanosheets or nanowires can be used to form gate-all-around (GAA) devices. Integration of GAA features around stacked nanosheets can be challenging. For instance, inner spacer formation is an important process to reduce capacitance and prevent leakage between gate stacks and source/drain regions in a stacked nanosheet GAA process flow. However, non-uniformities in the inner spacer thickness may expose portions of the source/drain regions which can degrade device performance. Thus, there is a need for improved designs and techniques for fabricating nanosheet GAA field effect transistor devices.

### SUMMARY

According to an embodiment of the present disclosure, a semiconductor structure includes a plurality of semiconductor layers vertically stacked over a semiconductor substrate, each of the plurality of semiconductor layers defining a channel region of the semiconductor structure, a source/drain region located on opposite ends of the plurality of semiconductor layers, a metal gate stack surrounding each of the plurality of semiconductor layers, and an inner spacer, having a concave surface curving inward in a direction towards the source/drain region, located between each of the plurality of semiconductor layers for separating the metal gate stack from the source/drain region. A surface of the inner spacer being in contact with a sidewall spacer located along opposite sidewalls of the metal gate stack. In an embodiment, the inner spacer has a shape that includes two opposite segments and a vertical segment, the two opposite segments are connected by the vertical segment in the shape of a letter “C”, the two opposite segments having a width that is larger than a width of the vertical segment. The concave surface of the inner spacer being relative to an outer surface of the metal gate stack for providing an uniform thickness to the inner spacer and protecting the source/drain region.

According to another embodiment of the present disclosure, a method of forming a semiconductor structure includes forming a plurality of semiconductor layers vertically stacked over a semiconductor substrate, each of the plurality of semiconductor layers defining a channel region of the semiconductor structure, forming a source/drain region located on opposite ends of the plurality of semiconductor layers, forming a metal gate stack surrounding each of the plurality of semiconductor layers, and forming an inner spacer having a concave surface curving inward in a direction towards the source/drain region between each of the plurality of semiconductor layers for separating the metal gate stack from the source/drain region. A surface of the inner spacer is in contact with a sidewall spacer being located along opposite sidewalls of the metal gate stack. In an embodiment, the inner spacer is formed with a shape that includes two opposite segments and a vertical segment, the two opposite segments are connected by the vertical segment in the shape of a letter “C”, the two opposite segments having a width that is larger than a width of the vertical segment. The concave surface of the inner spacer being relative to an outer surface of the metal gate stack for providing an uniform thickness to the inner spacer and protecting the source/drain region.

### BRIEF DESCRIPTION OF THE DRAWINGS

The following detailed description, given by way of example and not intended to limit the invention solely thereto, will best be appreciated in conjunction with the accompanying drawings, in which:

FIG. 1 is a three-dimensional (3D) view of a semiconductor structure at an intermediate step during a semiconductor manufacturing process, according to an embodiment of the present disclosure;

FIG. 1A is a cross-sectional view of the semiconductor structure taken along line A-A, according to an embodiment of the present disclosure;

FIG. 1B is a cross-sectional view of the semiconductor structure taken along line B-B, according to an embodiment of the present disclosure;

FIG. 1C is a cross-sectional view of the semiconductor structure taken along line C-C, according to an embodiment of the present disclosure;

FIG. 1D is a cross-sectional view of the semiconductor structure taken along line D-D, according to an embodiment of the present disclosure;

FIG. 2 is 3D view of the semiconductor structure after selectively etching sacrificial semiconductor layers, according to an embodiment of the present disclosure;

FIG. 2A is a cross-sectional view of the semiconductor structure taken along line A-A, according to an embodiment of the present disclosure;

FIG. 2B is a cross-sectional view of the semiconductor structure taken along line B-B, according to an embodiment of the present disclosure;

FIG. 2C is a cross-sectional view of the semiconductor structure taken along line C-C, according to an embodiment of the present disclosure;

FIG. 2D is a cross-sectional view of the semiconductor structure taken along line D-D, according to an embodiment of the present disclosure;

FIG. 3 is a 3D view of the semiconductor structure after depositing a sacrificial dielectric layer, according to an embodiment of the present disclosure;

FIG. 3A is a cross-sectional view of the semiconductor structure taken along line A-A, according to an embodiment of the present disclosure;

FIG. 3B is a cross-sectional view of the semiconductor structure taken along line B-B, according to an embodiment of the present disclosure;

FIG. 3C is a cross-sectional view of the semiconductor structure taken along line C-C, according to an embodiment of the present disclosure;

FIG. 3D is a cross-sectional view of the semiconductor structure taken along line D-D, according to an embodiment of the present disclosure;

FIG. 4 is a 3D view of the semiconductor structure after forming a sidewall spacer, according to an embodiment of the present disclosure;

FIG. 4A is a cross-sectional view of the semiconductor structure taken along line A-A, according to an embodiment of the present disclosure;

FIG. 4B is a cross-sectional view of the semiconductor structure taken along line B-B, according to an embodiment of the present disclosure;

FIG. 4C is a cross-sectional view of the semiconductor structure taken along line C-C, according to an embodiment of the present disclosure;

FIG. 4D is a cross-sectional view of the semiconductor structure taken along line D-D, according to an embodiment of the present disclosure;

FIG. 5 is a 3D view of the semiconductor structure after recessing a nanosheet fin, according to an embodiment of the present disclosure;

FIG. 5A is a cross-sectional view of the semiconductor structure taken along line A-A, according to an embodiment of the present disclosure;

FIG. 5B is a cross-sectional view of the semiconductor structure taken along line B-B, according to an embodiment of the present disclosure;

FIG. 5C is a cross-sectional view of the semiconductor structure taken along line C-C, according to an embodiment of the present disclosure;

FIG. 5D is a cross-sectional view of the semiconductor structure taken along line D-D, according to an embodiment of the present disclosure;

FIG. 6 is a 3D view of the semiconductor structure after removing the sacrificial dielectric layer, according to an embodiment of the present disclosure;

FIG. 6A is a cross-sectional view of the semiconductor structure taken along line A-A, according to an embodiment of the present disclosure;

FIG. 6B is a cross-sectional view of the semiconductor structure taken along line B-B, according to an embodiment of the present disclosure;

FIG. 6C is a cross-sectional view of the semiconductor structure taken along line C-C, according to an embodiment of the present disclosure;

FIG. 6D is a cross-sectional view of the semiconductor structure taken along line D-D, according to an embodiment of the present disclosure;

FIG. 7 is a 3D view of the semiconductor structure after recessing each of the sacrificial semiconductor layers, according to an embodiment of the present disclosure;

FIG. 7A is a cross-sectional view of the semiconductor structure taken along line A-A, according to an embodiment of the present disclosure;

FIG. 7B is a cross-sectional view of the semiconductor structure taken along line B-B, according to an embodiment of the present disclosure;

FIG. 7C is a cross-sectional view of the semiconductor structure taken along line C-C, according to an embodiment of the present disclosure;

FIG. 7D is a cross-sectional view of the semiconductor structure taken along line D-D, according to an embodiment of the present disclosure;

FIG. 8 is a 3D view of the semiconductor structure after forming inner spacers, according to an embodiment of the present disclosure;

FIG. 8A is a cross-sectional view of the semiconductor structure taken along line A-A, according to an embodiment of the present disclosure;

FIG. 8B is a cross-sectional view of the semiconductor structure taken along line B-B, according to an embodiment of the present disclosure;

FIG. 8C is a cross-sectional view of the semiconductor structure taken along line C-C, according to an embodiment of the present disclosure;

FIG. 8D is a cross-sectional view of the semiconductor structure taken along line D-D, according to an embodiment of the present disclosure;

FIG. 9 is a 3D view of the semiconductor structure 100 after forming source/drain regions and conducting a replacement metal gate process, according to an embodiment of the present disclosure;

FIG. 9A is a cross-sectional view of the semiconductor structure taken along line A-A, according to an embodiment of the present disclosure;

FIG. 9B is a cross-sectional view of the semiconductor structure taken along line B-B, according to an embodiment of the present disclosure;

FIG. 9C is a cross-sectional view of the semiconductor structure taken along line C-C, according to an embodiment of the present disclosure; and

FIG. 9D is a cross-sectional view of the semiconductor structure taken along line D-D, according to an embodiment of the present disclosure.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

It is understood that although the disclosed embodiments include a detailed description of an exemplary nanosheet FET architecture having silicon and silicon germanium nanosheets, implementation of the teachings recited herein are not limited to the particular FET architecture described herein. Rather, embodiments of the present invention are capable of being implemented in conjunction with any other type of FET device now known or later developed.

Fabrication of nanosheet FET semiconductor structures requires forming an inner spacer between adjacent nanosheets. The inner spacer acts to reduce the parasitic overlap capacitance between the gate and the source/drain regions. Parasitic capacitance contributes to undesired device effects such as resistive-capacitive (RC) delay, power dissipation, and cross-talk.

While the use of an inner spacer serves to reduce the parasitic overlap capacitance between the gate and the source/drain regions, variations in the inner spacer thickness introduce non-uniformities in the GAA nanosheet device that can expose portions of the source/drain regions to etching gases and chemicals used during the process of removing the sacrificial nanosheet layers, which may degrade integrated chip performance. More specifically, in current stacked nanosheet GAA process flow, a concave shape in (opposite) corner edges of the sacrificial nanosheet layers have been observed; mainly, at an interface between the sacrificial nanosheet layers and gate sidewall spacer. Generally, this concave shape is caused by non-uniform SiGe indentation; thus, SiGe etching at the interface between the sacrificial nanosheet layers and gate sidewall spacer will be slower.

During inner spacer deposition, this concave shape in the outer corners of the sacrificial nanosheets introduces non-uniformities in the inner spacer thickness. Consequently, during removal of the sacrificial nanosheet layers (i.e., channel release) active regions (e.g., source/drain regions) of the nanosheet GAA device can be exposed due to the non-uniform thickness of the inner spacer making these regions susceptible to attack by etching gases and chemicals. Accordingly, to improve process control it is desirable to have a well-defined inner spacer region with uniform dimensions.

Therefore, embodiments of the present disclosure provide a semiconductor structure, and a method of making the same, in which the inner spacer is formed with a concave shape inverse to the concave shape typically observed in the sacrificial nanosheet layers. The concave shape of the inner spacer material is relative to the sacrificial nanosheet layers and includes a thicker portion of the inner spacer material being located at an interface between the inner spacer material and the gate sidewall spacer for protecting source/drain regions during nanosheet channel release.

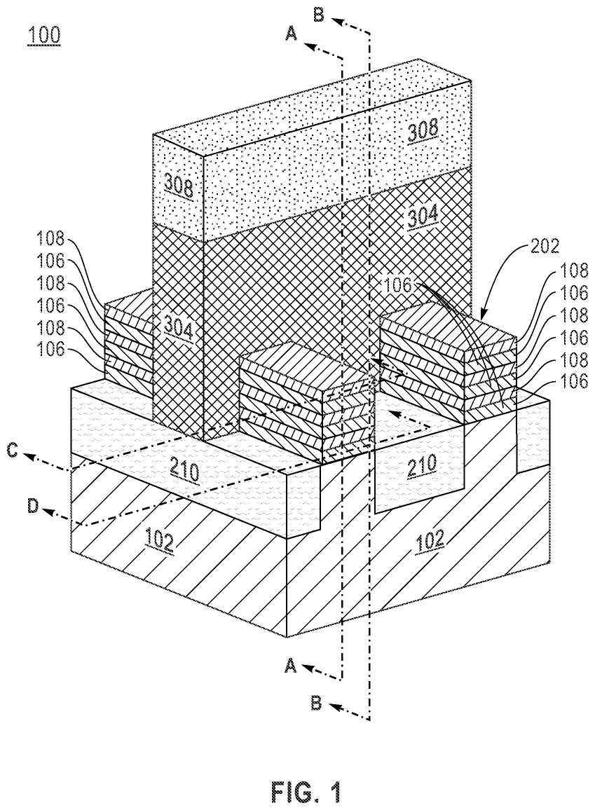

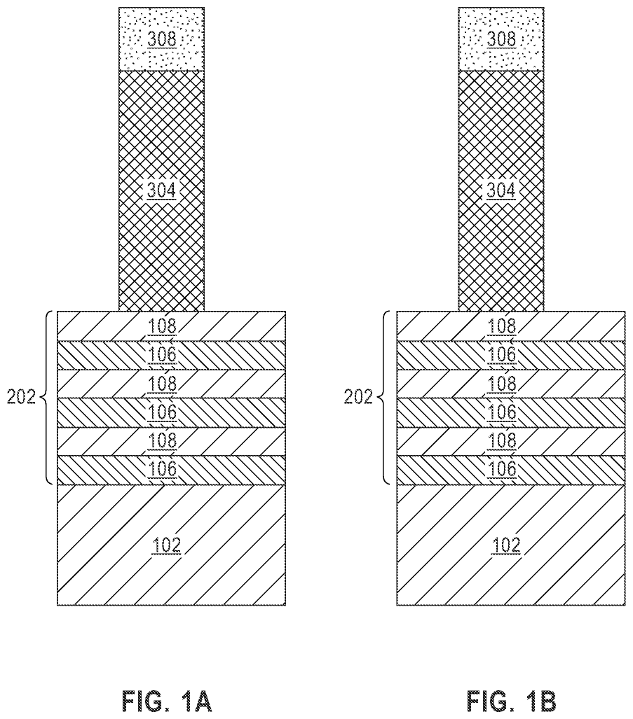

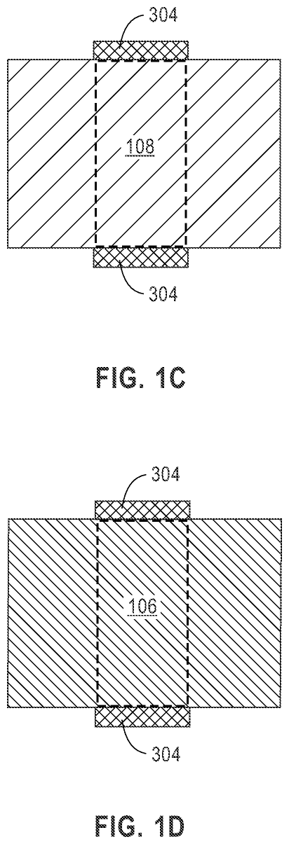

One way to form the inner spacer with (inverse) concave shape may include partially recessing outmost portions of the sacrificial semiconductor layers, depositing a sacrificial dielectric layer, forming the gate sidewall spacer, etching nanosheet fins, removing the sacrificial dielectric layer, perform indentation of sacrificial semiconductor layers, and depositing the inner spacer material. Embodiments by which the concave shape inner spacer can be formed are described in detailed below by referring to the accompanying drawings in FIGS. 1-9D.

Referring now to FIG. 1, a 3D view of a semiconductor structure 100 is shown at an intermediate step during a semiconductor manufacturing process, according to an embodiment of the present disclosure. In this embodiment, FIG. 1A is a cross-sectional view of the semiconductor structure 100 taken along line A-A; FIG. 1B is a cross-sectional view of the semiconductor structure 100 taken along line B-B; FIG. 1C is a cross-sectional view of the semiconductor structure 100 taken along line C-C; and FIG. 1D is a cross-sectional view of the semiconductor structure 100 taken along line D-D.

For ease of illustration and description of the present embodiments, all subsequent figures accompanied by the letter A are cross-sections taken along line A-A corresponding to a cut across a first region of the semiconductor structure 100 including a dummy gate 304, a hard mask 308, and a nanosheet fin 202, as shown in FIG. 1; all subsequent figures accompanied by the letter B are cross-sections taken along line B-B corresponding to a cut across a second region of the semiconductor structure 100 including the dummy gate 304, the hard mask 308, and the nanosheet fin 202, as shown in FIG. 1; all subsequent figures accompanied by the letter C are cross-sections taken along line C-C corresponding to a cut along a semiconductor channel layer 108, as shown in FIG. 1; and all subsequent figures accompanied by the letter D are cross-sections taken along line D-D corresponding to a cut along a sacrificial semiconductor layer 106, as shown in FIG. 1. The first region of the semiconductor structure 100 (line A-A) is located in a central or middle portion of the nanosheet fin 202, while the second region of the semiconductor structure 100 (line B-B) is located towards an edge of the nanosheet fin 202, as depicted in FIG. 1.

Known processing techniques have been applied to the semiconductor structure 100 shown in FIG. 1. At this step of the manufacturing process, an alternating sequence of layers of sacrificial semiconductor material and layers of semiconductor channel material vertically stacked one on top of another in a direction perpendicular to the semiconductor substrate 102 can be deposited to form a nanosheet stack. Specifically, the alternating sequence includes alternating sacrificial semiconductor layers 106 and semiconductor channel layers 108 formed in a stack above the semiconductor substrate 102. The term sacrificial, as used herein, means a layer or other structure, that is (or a part thereof is) removed before completion of the final device. For instance, in the example being described, portions of the sacrificial semiconductor layers 106 will be removed from the stack in the channel region of the device to permit the semiconductor channel layers 108 to be released from the nanosheet stack. It is notable that while in the present example the sacrificial semiconductor layers 106 and the semiconductor channel layers 108 are made of silicon germanium (SiGe) and silicon (Si), respectively, any combination of sacrificial and channel materials may be employed in accordance with the present techniques. For example, one might instead employ selective etching technology which permits Si to be used as the sacrificial material between SiGe channel layers.

The semiconductor substrate 102 may be, for example, a bulk substrate, which may be made from any of several known semiconductor materials such as, for example, silicon, germanium, silicon-germanium alloy, and compound (e.g. III-V and II-VI) semiconductor materials. Non-limiting examples of compound semiconductor materials include gallium arsenide, indium arsenide, and indium phosphide, or indium gallium phosphide. Typically, the semiconductor substrate 102 may be approximately, but is not limited to, several hundred microns thick. In other embodiments, the semiconductor substrate 102 may be a layered semiconductor such as a silicon-on-insulator or SiGe-on-insulator, where a buried insulator layer, separates a base substrate from a top semiconductor layer.

In general, layers in the nanosheet stack (e.g., SiGe/Si layers) can be formed by epitaxial growth by using the semiconductor substrate 102 as the seed layer. Terms such as “epitaxial growth and/or deposition” and “epitaxially formed and/or grown” refer to the growth of a semiconductor material on a deposition surface of a semiconductor material, in which the semiconductor material being grown has the same or substantially similar crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same or substantially similar crystalline characteristics as the deposition surface on which it is formed. For example, an epitaxial semiconductor material deposited on a {100} crystal surface will take on a {100} orientation. In some embodiments, epitaxial growth and/or deposition processes are selective to forming on a semiconductor surface, and do not deposit material on dielectric surfaces, such as silicon dioxide or silicon nitride surfaces.

Non-limiting examples of various epitaxial growth processes include rapid thermal chemical vapor deposition (RTCVD), low-energy plasma deposition (LEPD), ultra-high vacuum chemical vapor deposition (UHVCVD), atmospheric pressure chemical vapor deposition (APCVD), metalorganic chemical vapor deposition (MOCVD), low-pressure chemical vapor deposition (LPCVD), limited reaction processing CVD (LRPCVD), and molecular beam epitaxy (MBE). The temperature for an epitaxial deposition process can range from 500° C. to 900° C. Although higher temperatures typically results in faster deposition, the faster deposition may result in crystal defects and film cracking.

A number of different precursors may be used for the epitaxial growth of the alternating sequence of SiGe/Si layers in the nanosheet stack. In some embodiments, a gas source for the deposition of epitaxial semiconductor material includes a silicon containing gas source, a germanium containing gas source, or a combination thereof. For example, an epitaxial silicon layer may be deposited from a silicon gas source including, but not necessarily limited to, silane, disilane, trisilane, tetrasilane, hexachlorodisilane, tetrachlorosilane, dichlorosilane, trichlorosilane, and combinations thereof. An epitaxial germanium layer can be deposited from a germanium gas source including, but not necessarily limited to, germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, helium and argon can be used.

With continued reference to FIG. 1, the sacrificial semiconductor layers 106 are formed by epitaxially growing a layer of SiGe. In this embodiment, the germanium concentration of the sacrificial semiconductor layers 106 varies from approximately 10 atomic percent to approximately 50 atomic percent. In an exemplary embodiment, the sacrificial semiconductor layers 106 are made of SiGe with a germanium concentration of approximately 30 atomic percent.

To continue building the nanosheet stack, the semiconductor channel layers 108 are formed by epitaxially growing a Si layer. As depicted in the figure, the sacrificial semiconductor layers 106 and the semiconductor channel layers 108 have a substantially similar or identical thickness. As shown in FIG. 1, the nanosheet stack is grown by forming (SiGe) sacrificial semiconductor layers 106 and (Si) semiconductor channel layers 108 in an alternating manner onto the semiconductor substrate 102. Accordingly, each of the sacrificial semiconductor layers 106 and the semiconductor channel layers 108 in the nanosheet stack can be formed in the same manner as described above, e.g., using an epitaxial growth process, to a thickness varying from approximately 5 nm to approximately 10 nm, although other thicknesses are within the contemplated scope of the invention.

Thus, each of the layers in the nanosheet stack have nanoscale dimensions, and thus can also be referred to as nanosheets. Further, as highlighted above, the (Si) semiconductor channel layers 108 in the nanosheet stack will be used to form the channel layers of the device. Consequently, the dimensions of the semiconductor channel layers 108 dictate the dimensions of the channel region of the semiconductor structure 100. In some embodiments, the semiconductor channel layers 108 may include nanowires or nano-ellipses.

As highlighted above, the goal is to produce a stack of alternating (sacrificial and channel) SiGe and Si layers on the wafer. The number of layers in the stack can be tailored depending on the particular application. Thus, the configurations depicted and described herein are merely examples meant to illustrate the present techniques. For instance, the present nanosheet stack can contain more or fewer layers than are shown in the figures.

The nanosheet stack can be used to produce a gate all around (GAA) device that includes vertically stacked semiconductor channel material nanosheets for a positive channel Field Effect Transistor (hereinafter “p-FET”) or a negative channel Field Effect Transistor (hereinafter “n-FET”) device.

The nanosheet stack is subsequently pattern to form the nanosheet fin 202 using, for example, a photolithographic patterning and etching process that removes portions of the nanosheet stack and portions of the semiconductor substrate 102, as depicted in FIG. 1. Any suitable etching process can be used such as, for example, reactive ion etching (RIE).

Etching generally refers to the removal of a material from a substrate (or structures formed on the substrate), and is often performed with a mask in place so that material may selectively be removed from certain areas of the substrate, while leaving the material unaffected, in other areas of the substrate. There are generally two categories of etching, (i) wet etch and (ii) dry etch. Wet etch is performed with a solvent (such as an acid) which may be chosen for its ability to selectively dissolve a given material (such as oxide), while, leaving another material (such as polysilicon) relatively intact. This ability to selectively etch given materials is fundamental to many semiconductor fabrication processes. A wet etch will generally etch a homogeneous material (e.g., oxide) isotropically, but a wet etch may also etch single-crystal materials (e.g., silicon wafers) anisotropically. Dry etch may be performed using a plasma. Plasma systems can operate in several modes by adjusting the parameters of the plasma. Ordinary plasma etching produces energetic free radicals, neutrally charged, that react at the surface of the wafer. Since neutral particles attack the wafer from all angles, this process is isotropic. Ion milling, or sputter etching, bombards the wafer with energetic ions of noble gases which approach the wafer approximately from one direction, and therefore this process is highly anisotropic. RIE operates under conditions intermediate between sputter and plasma etching and may be used to produce deep, narrow features, such as shallow trench isolation (STI) trenches.

It should be noted that portions of the semiconductor substrate 102 removed during the photolithographic patterning process are subsequently filled with an insulating material to form STI regions 210. The process of forming the STI regions 210 is standard and well-known in the art, it typically involves depositing the insulating material to substantially fill areas of the semiconductor structure 100 between adjacent nanosheet fins 202 (not shown) for electrically isolating the nanosheet fin 202. The STI regions 210 may be formed by, for example, chemical vapor deposition (CVD) of a dielectric material. Non-limiting examples of dielectric materials to form the STI regions 210 include silicon oxide, silicon nitride, hydrogenated silicon carbon oxide, silicon based low-k dielectrics, flowable oxides, porous dielectrics, or organic dielectrics including porous organic dielectrics.

According to an embodiment, the dummy gate 304 is formed and patterned over a top surface and along sidewalls of the nanosheet fin 202. The dummy gate 304 can be formed using conventional techniques known in the art. For example, the dummy gate 304 may be formed from amorphous silicon (a-Si). A hard mask 308 is typically formed over the dummy gate 304 to act as an etch stop. The hard mask 308 is generally formed from silicon nitride, silicon oxide, an oxide/nitride stack, or similar materials and configurations.

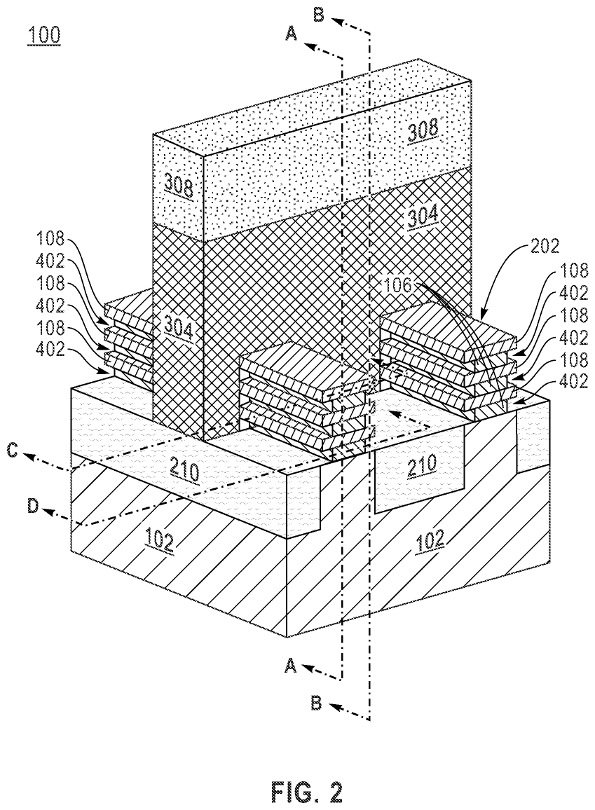

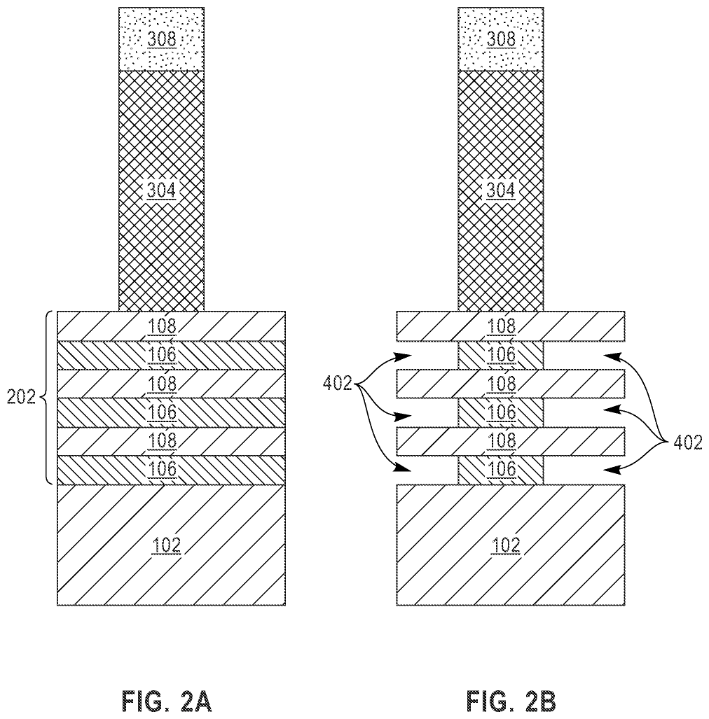

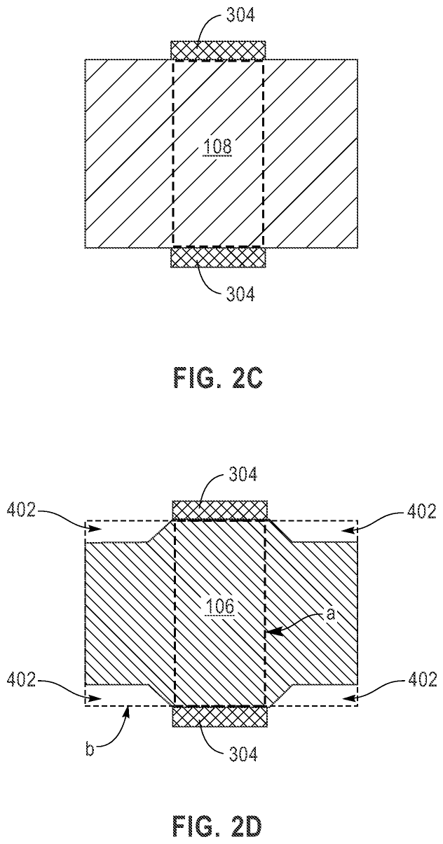

Referring now to FIG. 2, a 3D view of the semiconductor structure 100 is shown after selectively etching the sacrificial semiconductor layers 106, according to an embodiment of the present disclosure. In this embodiment, FIG. 2A is a cross-sectional view of the semiconductor structure 100 taken along line A-A; FIG. 2B is a cross-sectional view of the semiconductor structure 100 taken along line B-B; FIG. 2C is a cross-sectional view of the semiconductor structure 100 taken along line C-C; and FIG. 2D is a cross-sectional view of the semiconductor structure 100 taken along line D-D.

In this embodiment, outermost portions of each of the sacrificial semiconductor layers 106 are selectively recessed using, for example, a selective etch process such as a hydrogen chloride (HCL) gas etch or wet removal process. As depicted in FIG. 2, the outermost portions of the sacrificial semiconductor layers 106 are located within the second region depicted by line B-B. Preferably, the selected etch process for recessing the sacrificial semiconductor layers 108 is capable of etching silicon germanium without attacking silicon, as depicted in FIG. 2B.

Etching of the sacrificial semiconductor layers 106 (SiGe indentation) is conducted until approximately 2-10 nm of the semiconductor material (e.g., SiGe) forming the sacrificial semiconductor layers 106 have been removed such that a length or horizontal width of each of the sacrificial semiconductor layers 106 is less than a width of the semiconductor channel layers 108 in the stack, as depicted in FIG. 2B. Recessing the sacrificial semiconductor layers 106 forms first indentation regions 402 on opposite sides or ends of the recessed sacrificial semiconductor layers 106, as depicted in FIGS. 2, 2B and 2D. Specifically, FIG. 2D shows the cut along a sacrificial semiconductor layer 106, with the central dotted region “a” depicting an area covered by the dummy gate 304 and an outer dotted region “b” depicting a total area of the sacrificial semiconductor layer 106.

As can be observed in FIG. 2D, a first portion of the sacrificial semiconductor layer 106 is in contact with the dummy gate 304, while a second portion of the sacrificial semiconductor layer 106 extending outwards from the dotted region “a” includes opposite sidewalls with a reverse taper profile. A conformal dielectric material can be subsequently deposited in the first indentation regions 402 for protecting edges of the sacrificial semiconductor layers 106. The subsequently deposited dielectric pinches-off the first indentation regions 402, as will be described below. It should be noted that by performing this step opposite corner edges of the sacrificial semiconductor layer 106 do not form the concave shape observed during typical nanosheet GAA process flow described above.

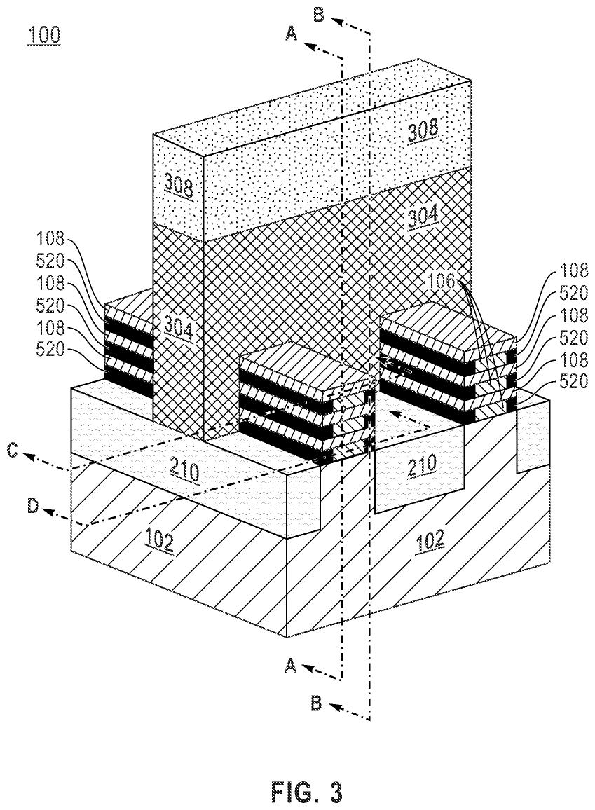

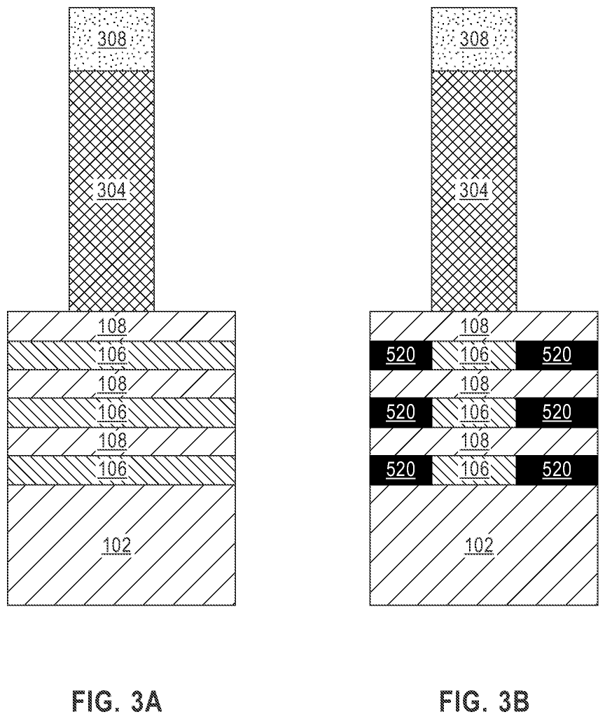

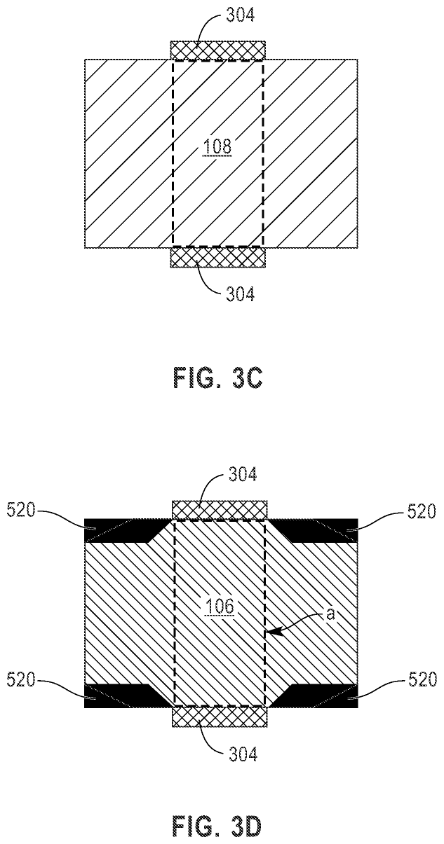

Referring now to FIG. 3, a 3D view of the semiconductor structure 100 is shown after depositing a sacrificial dielectric layer 520, according to an embodiment of the present disclosure. In this embodiment, FIG. 3A is a cross-sectional view of the semiconductor structure 100 taken along line A-A; FIG. 3B is a cross-sectional view of the semiconductor structure 100 taken along line B-B; FIG. 3C is a cross-sectional view of the semiconductor structure 100 taken along line C-C; and FIG. 3D is a cross-sectional view of the semiconductor structure 100 taken along line D-D.

According to an embodiment, the sacrificial dielectric layer 520 can be formed by conformal deposition of a dielectric material that pinches-off the first indentation regions 402 shown in FIGS. 2, 2B and 2D. Preferably, the dielectric material forming the sacrificial dielectric layer 520 includes, for instance, an oxide dielectric material deposited by atomic layer deposition (ALD), chemical vapor deposition (CVD), or any other suitable deposition processes. More particularly, in an embodiment, the sacrificial dielectric layer 520 may be composed of a material that have good etch selectivity to the sacrificial semiconductor layers 106 (i.e., SiGe with low Ge concentration) including, for example, SiO₂, SiBCN, SiCN, SiOCN, Ge, SiGe, and the like. A thickness of the sacrificial dielectric layer 520 may vary from approximately 2 nm to approximately 6 nm, and ranges therebetween. An etch-back process is then conducted on the semiconductor structure 100 to remove excess portions of the sacrificial dielectric layer 520.

As can be appreciated in the figures, the sacrificial dielectric layer 520 deposits on surfaces of the STI regions 210, sacrificial semiconductor layers 106 and semiconductor channel layers 108 exposed by the first indentation regions 402 (FIG. 2) substantially filling a space between semiconductor channel layers 108.

By forming the sacrificial dielectric layer 520 edges of the sacrificial semiconductor layers 106 may preserve a substantially squared or uniform shape in the gate region depicted by dotted line “a” (i.e., gate region), unlike current stacked nanosheet GAA process flow in which etch chemistry can cause the sacrificial dielectric layer 520 to have (non-uniform) concave edges. Thus, the formed sacrificial semiconductor layers 106 without the concave shape at outer corners may allow the inner spacer material being deposited with an uniform thickness that can efficiently protect source/drain regions during channel release and separate subsequently formed metal gate stack from the source/drain regions.

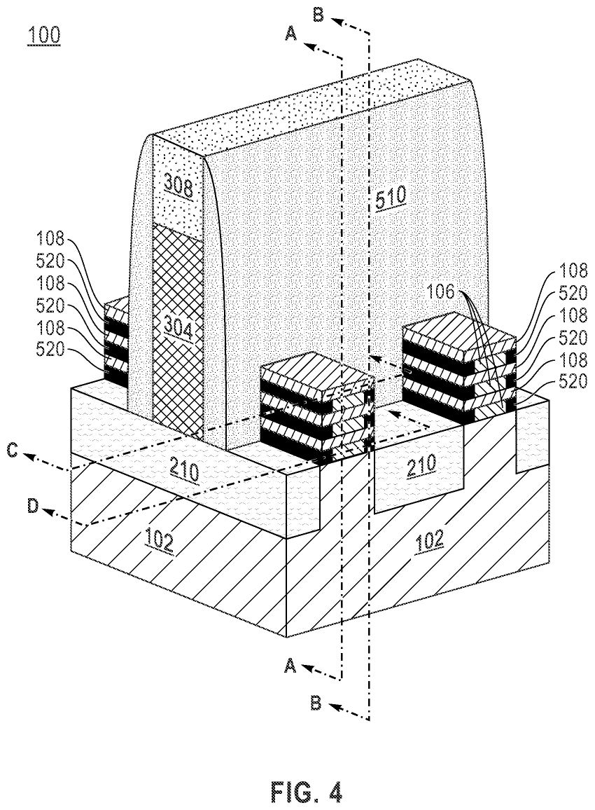

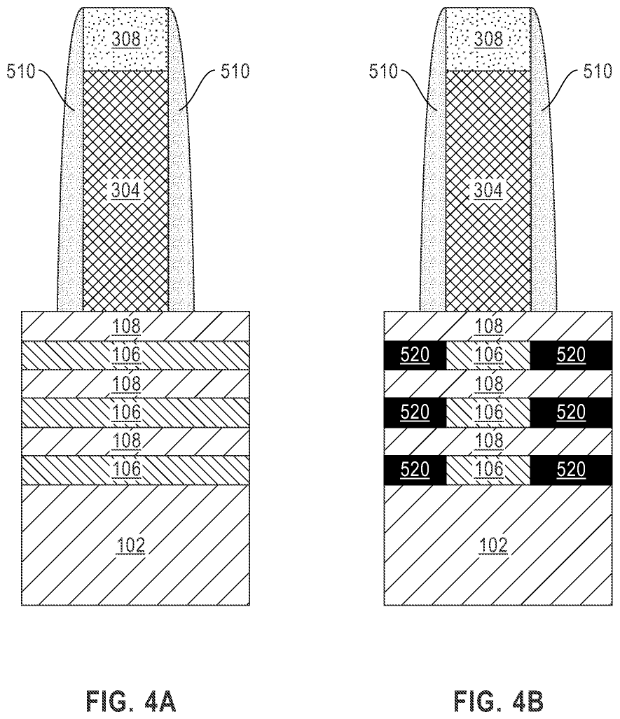

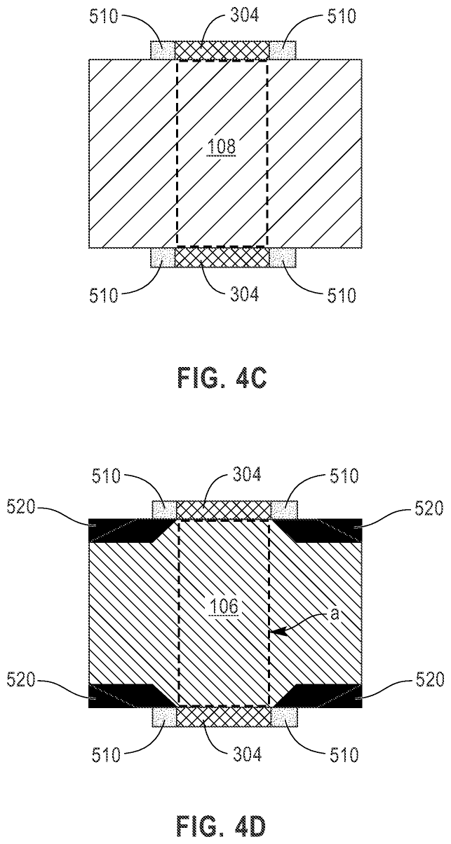

Referring now to FIG. 4, a 3D view of the semiconductor structure 100 is shown after forming a sidewall spacer 510, according to an embodiment of the present disclosure. In this embodiment, FIG. 4A is a cross-sectional view of the semiconductor structure 100 taken along line A-A; FIG. 4B is a cross-sectional view of the semiconductor structure 100 taken along line B-B; FIG. 4C is a cross-sectional view of the semiconductor structure 100 taken along line C-C; and FIG. 4D is a cross-sectional view of the semiconductor structure 100 taken along line D-D.

In this embodiment, a spacer material has been deposited along sidewalls of the dummy gate 304 and along sidewalls of the hard mask 308 to form the sidewall spacer 510, as depicted in FIGS. 4 and 4B. As shown in FIG. 4D, the sidewall spacer 510 is in contact with the sacrificial dielectric layer 520.

In one or more embodiments, the sidewall spacer 510 can be formed using a spacer pull down formation process. The sidewall spacer 510 can also be formed using a sidewall image transfer (SIT) spacer formation process, which includes spacer material deposition followed by directional RIE of the deposited spacer material. Non-limiting examples of various spacer materials for forming the sidewall spacer 510 may include conventional low-k materials such as SiO₂, SiOC, SiOCN, or SiBCN. Typically, a thickness of the sidewall spacer 510 may vary from approximately 5 nm to approximately 20 nm, and ranges therebetween.

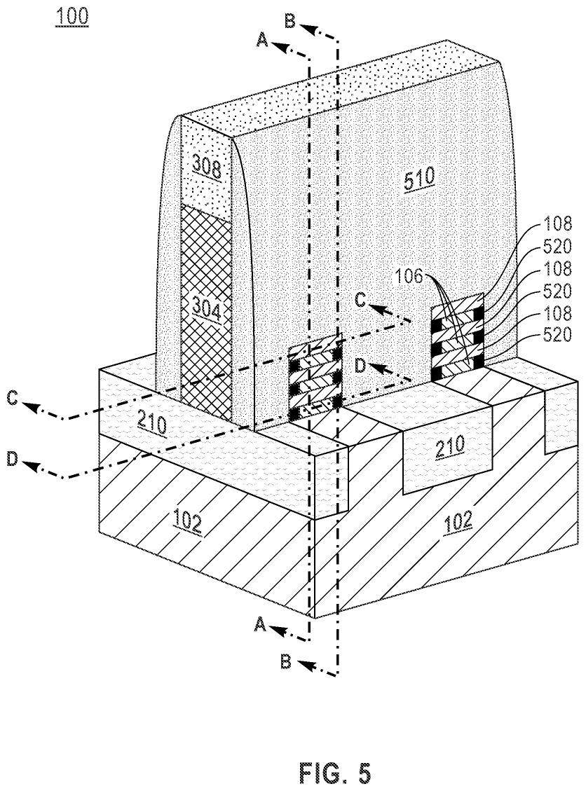

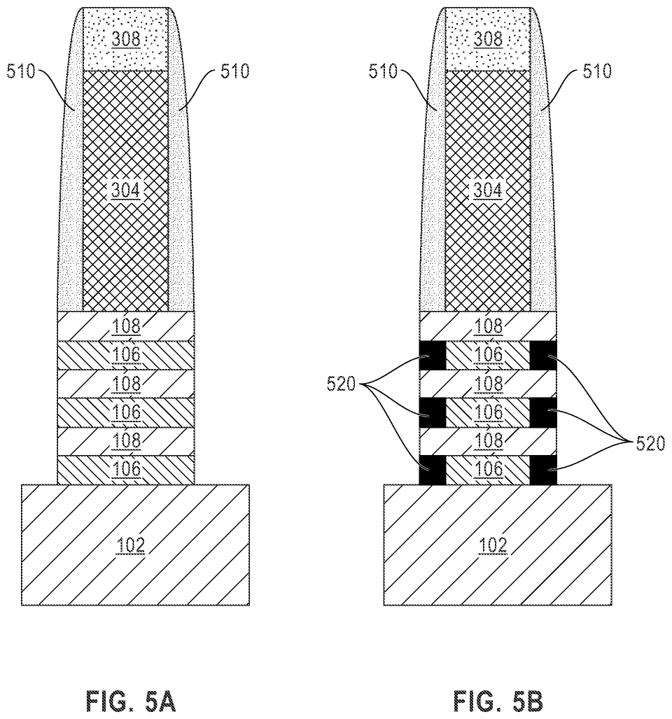

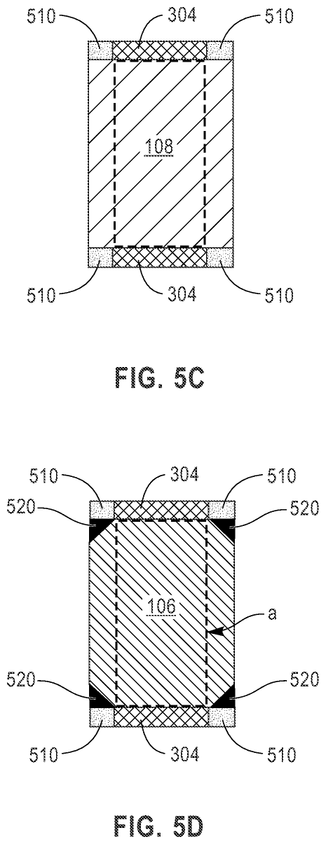

Referring now to FIG. 5, a 3D view of the semiconductor structure 100 is shown after recessing the nanosheet fin 202, according to an embodiment of the present disclosure. In this embodiment, FIG. 5A is a cross-sectional view of the semiconductor structure 100 taken along line A-A; FIG. 5B is a cross-sectional view of the semiconductor structure 100 taken along line B-B; FIG. 5C is a cross-sectional view of the semiconductor structure 100 taken along line C-C; and FIG. 5D is a cross-sectional view of the semiconductor structure 100 taken along line D-D.

As known by those skilled in the art, the sidewall spacer 510 can be used as a mask, to recess portions of the nanosheet fin 202 extending outwards from the sidewall spacer 510, i.e., portions of the nanosheet fin 202 that are not covered by the sidewall spacer 510 and dummy gate 304, as illustrated in FIGS. 5A-5B. For example, a RIE process can be used to recess the portions of the nanosheet fin 202 that are not under the sidewalls spacer 510 and dummy gate 304. Recessing the nanosheet fin 202 forms source/drain recesses (not shown) that allow the subsequent formation of source/drain regions in the semiconductor structure 100, as will be described in detail below.

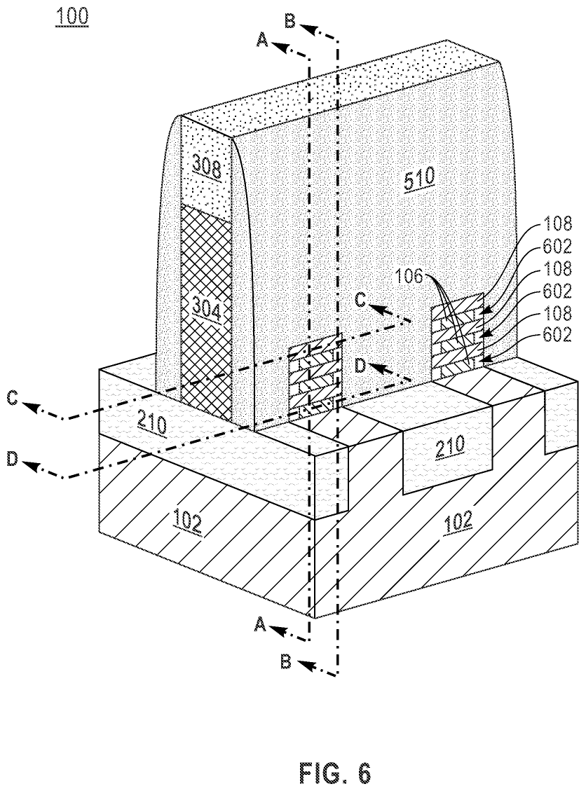

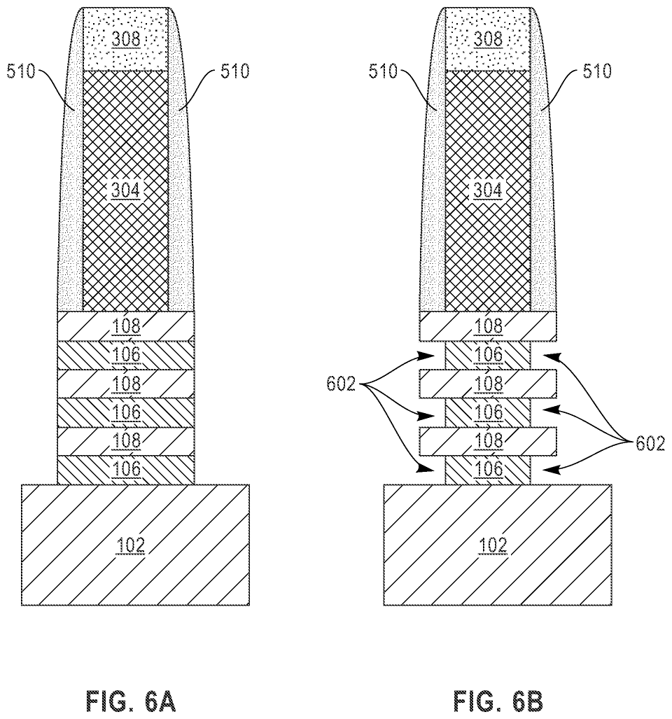

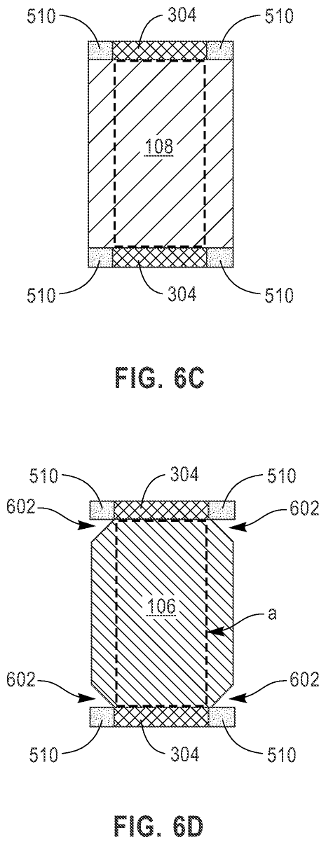

Referring now to FIG. 6, a 3D view of the semiconductor structure 100 is shown after removing the sacrificial dielectric layer 520, according to an embodiment of the present disclosure. In this embodiment, FIG. 6A is a cross-sectional view of the semiconductor structure 100 taken along line A-A; FIG. 6B is a cross-sectional view of the semiconductor structure 100 taken along line B-B; FIG. 6C is a cross-sectional view of the semiconductor structure 100 taken along line C-C; and FIG. 6D is a cross-sectional view of the semiconductor structure 100 taken along line D-D.

In the depicted embodiment, a selective etching technique can be used to remove the sacrificial dielectric layer 520, shown in FIGS. 5, 5B and 5D, from the semiconductor structure 100. Non-limiting examples of etching techniques for removing the sacrificial dielectric layer 520 may include dry methods such as reactive ion etch (RIE), or wet removal processes. Removal of the sacrificial dielectric layer 520 (FIGS. 5, 5B and 5D) forms second indentation regions 602 on opposite sidewalls of the sacrificial semiconductor layers 106, as depicted in FIGS. 6, 6B and 6D.

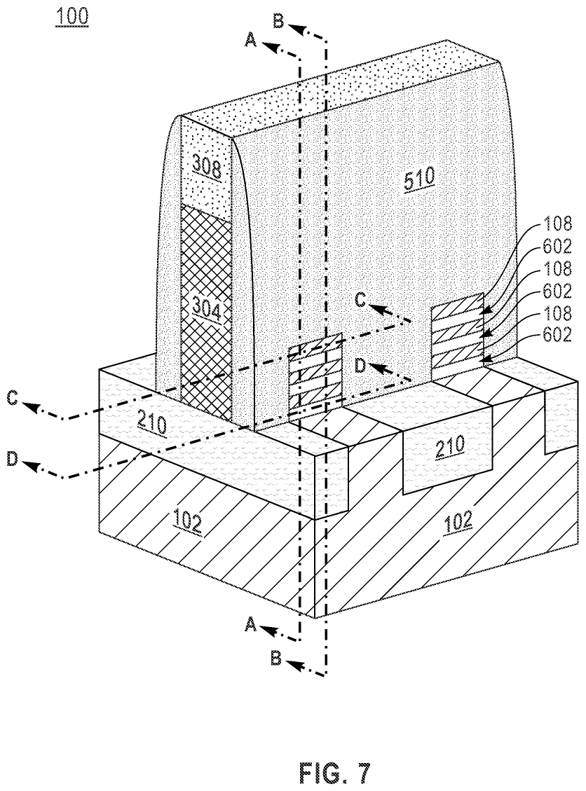

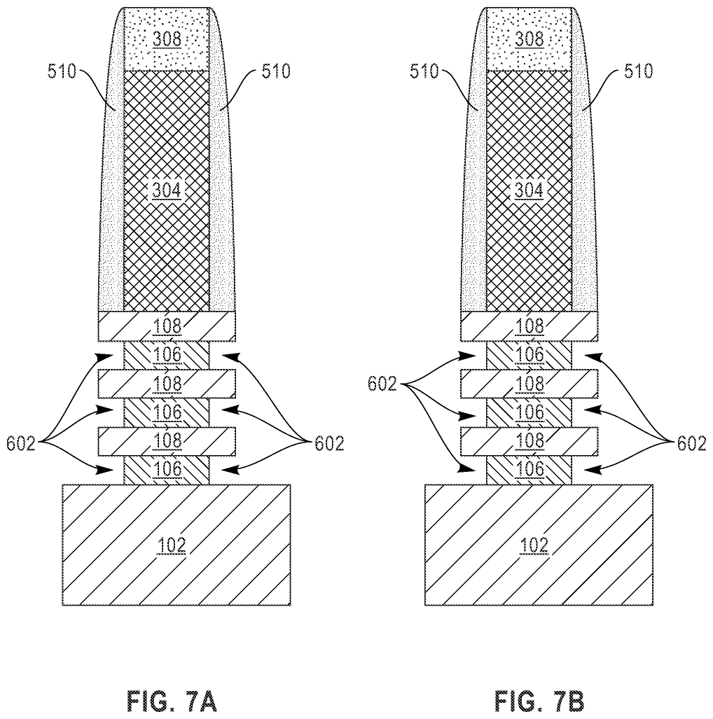

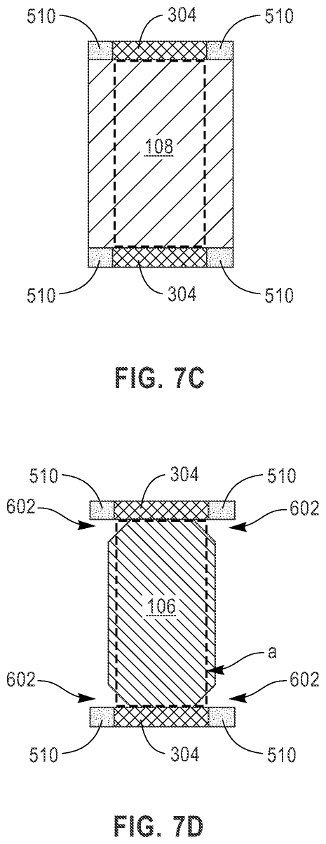

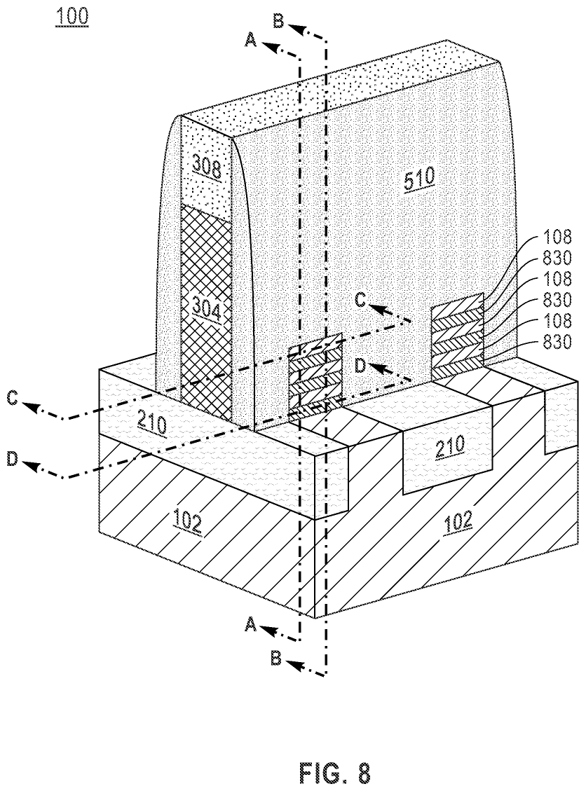

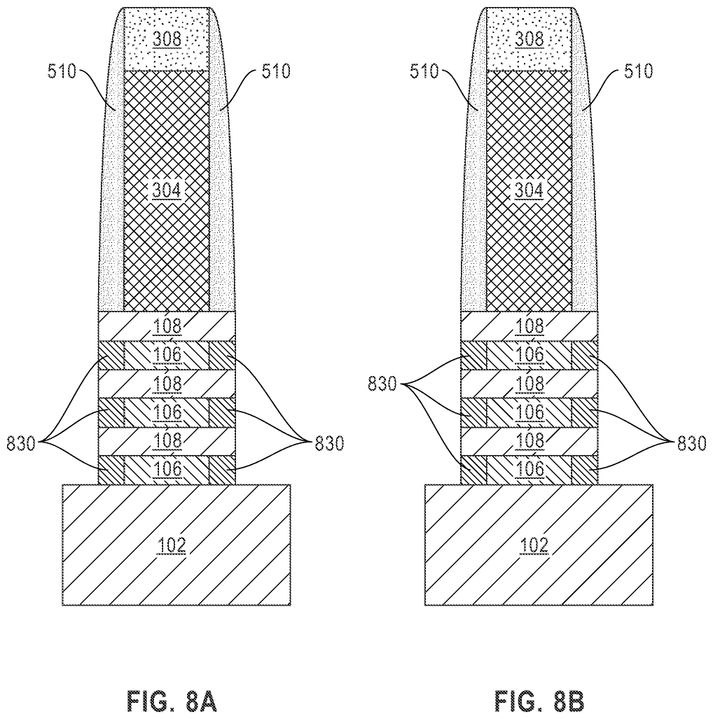

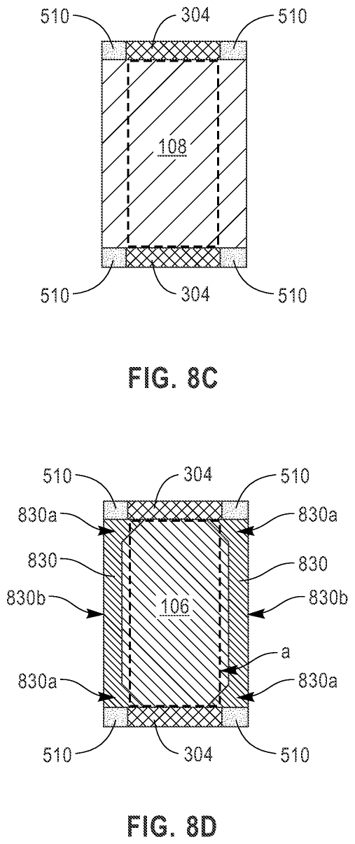

Referring now to FIG. 7 and FIG. 8 simultaneously, 3D views of the semiconductor structure 100 are shown after recessing each of the sacrificial semiconductor layers 106 and forming inner spacers 830, according to an embodiment of the present disclosure. In this embodiment, FIG. 7A is a cross-sectional view of the semiconductor structure 100 taken along line A-A; FIG. 7B is a cross-sectional view of the semiconductor structure 100 taken along line B-B; FIG. 7C is a cross-sectional view of the semiconductor structure 100 taken along line C-C; and FIG. 7D is a cross-sectional view of the semiconductor structure 100 taken along line D-D. Similarly, FIG. 8A is a cross-sectional view of the semiconductor structure 100 taken along line A-A; FIG. 8B is a cross-sectional view of the semiconductor structure 100 taken along line B-B; FIG. 8C is a cross-sectional view of the semiconductor structure 100 taken along line C-C; and FIG. 8D is a cross-sectional view of the semiconductor structure 100 taken along line D-D.

After removing the sacrificial dielectric layer 520 (FIGS. 5, 5B and 5D), outer portions of each of the sacrificial semiconductor layers 106 are selectively recessed using, for example, a selective etch process such as a hydrogen chloride (HCL) gas etch or wet removal process. Preferably, the selected etch process for recessing the sacrificial semiconductor layers 106 is capable of etching silicon germanium without attacking silicon. Etching the sacrificial semiconductor layers 106 extends the second indentation regions 602, as depicted in the figures. A length or horizontal thickness of each of the sacrificial semiconductor layers 106 after the etching process may vary between approximately 10 nm and approximately 20 nm, and ranges therebetween. As can be observed, the length or horizontal width of each of the sacrificial semiconductor layers 106 is less than a width of the semiconductor channel layers 108 in the stack, as depicted now in FIGS. 7A-7B.

According to an embodiment, the inner spacers 830 may be formed within the second indentation regions 602 after etching the sacrificial semiconductor layers 106 (SiGe indentation). The inner spacers 830 can be formed, for example, by conformal deposition of an inner spacer dielectric material that pinches off the second indentation regions 602 formed after recessing the sacrificial semiconductor layers 106. The inner spacers 830 may include any suitable dielectric material, such as silicon dioxide, silicon nitride, SiOC, SiOCN, SiBCN, and may include a single layer or multiple layers of dielectric materials. An isotropic etch can then be conducted to remove excess inner spacer material from other regions of the semiconductor structure 100.

As depicted in FIGS. 8A-8B, outer sidewalls of the inner spacers 830 are vertically aligned with the semiconductor channel layers 108, and thus with the sidewall spacer 510 located on opposing sidewalls of the dummy gate 304. As shown in FIGS. 8A8B, the inner spacer 830 is located between each of the semiconductor channel layers 108.

More particularly, as depicted in FIG. 8D, the inner spacer 830 has a concave surface, relative to the sacrificial semiconductor layer 106, curving inward such that opposite outer portions of the inner spacer 830 are wider than a middle portion of the inner spacer 830. The wider outer or corner portions of the inner spacer 830 substantially covers the sidewall spacer 510 and outermost portions of the dummy gate 304, as depicted in FIG. 8D. In one or more embodiments, the concave shape of the inner spacer 830 may resemble the letter “C”. More particularly, the inner spacer 830 has a shape that includes two opposite segments 830a and a vertical segment 830b, the two opposite segments 830a being connected or linked by the vertical segment 830b in the shape of the letter “C”. The two opposite segments 830a have a width that is larger than a width of the vertical segment 830b.

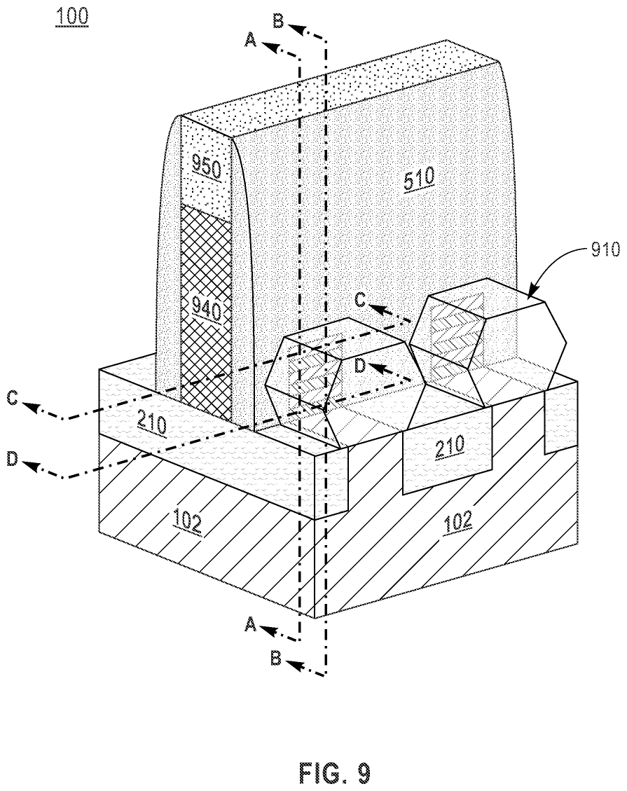

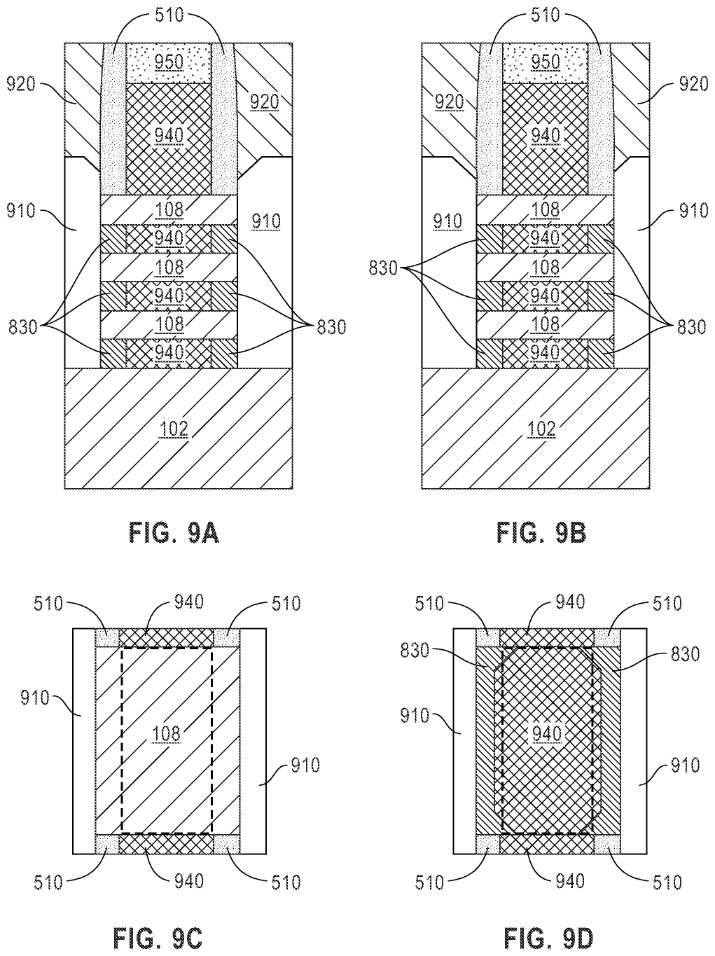

Referring now to FIG. 9, a 3D view of the semiconductor structure 100 is shown after forming source/drain regions 910 and conducting a replacement metal gate process, according to an embodiment of the present disclosure. In this embodiment, FIG. 9A is a cross-sectional view of the semiconductor structure 100 taken along line A-A; FIG. 9B is a cross-sectional view of the semiconductor structure 100 taken along line B-B; FIG. 9C is a cross-sectional view of the semiconductor structure 100 taken along line C-C; and FIG. 9D is a cross-sectional view of the semiconductor structure 100 taken along line D-D.

After forming the inner spacers 830, source/drain regions 910 can be formed on the source/drain recesses (not shown) formed after etching the nanosheet fin 202 described above with reference to FIG. 5. The source/drain regions 910 can be formed using an epitaxial layer growth process on the exposed ends of the semiconductor channel layers 108.

As depicted in FIGS. 9A-9B, the source/drain regions 910 are formed on opposing sides of the nanosheet fins 202 in direct contact with end portions of the semiconductor channel layers 108 and end portions of the inner spacers 830 surrounding the sacrificial semiconductor layers 106 (FIGS. 8A-8B). The source/drain regions 910 are formed above the semiconductor substrate 102. Although not depicted in the figures, typically a bottom dielectric isolation region is formed between the semiconductor substrate 102 and the nanosheet fin 202 for isolating the source/drain regions 910, thereby preventing epitaxial growth from the semiconductor substrate 102.

According to an embodiment, a dielectric layer 920 is formed to fill voids in the semiconductor structure 100. Specifically, the dielectric layer 920 fills a space remaining above the source/drain regions 910. The dielectric layer 920 can be formed by, for example, CVD of a dielectric material. Non-limiting examples of dielectric materials to form the dielectric layer 920 may include silicon oxide, silicon nitride, hydrogenated silicon carbon oxide, silicon based low-k dielectrics, flowable oxides, porous dielectrics, or organic dielectrics including porous organic dielectrics.

After deposition of the dielectric layer 920, a planarization process, such as a chemical mechanical polishing (CMP), can be conducted on the semiconductor structure 100. This process may expose a top surface of the dummy gate 304 in preparation for removal of the dummy gate 304 (i.e., gate replacement), depicted in FIGS. 8-8D. Known etching processes can be used to remove the dummy gate 304 (FIGS. 8-8D) including, for example, RIE or chemical oxide removal (COR). In a gate-last fabrication process, the removed dummy gate 304 (FIGS. 8-8D) is thereafter replaced with a metal gate as known in the art. Recesses (not shown) may remain in the semiconductor structure 100 after removal of the dummy gate 304 (FIGS. 8-8D) exposing the semiconductor channel layers 108.

The sacrificial semiconductor layers 106 can now be removed from the semiconductor structure 100 (SiGe release). In an exemplary embodiment, the sacrificial semiconductor layers 106 can be removed by known etching processes including, for example, RIE, wet etch or dry gas (HCl). As known by those skilled in the art, removing the sacrificial semiconductor layers 106 create a plurality of recesses (not shown) between inner spacers 830 and semiconductor channel layers 108 that will subsequently be filled with corresponding work function metals, as will be described in detail below.

In one or more embodiments, after removing the sacrificial semiconductor layers 106, a high-k pre-clean is conducted on the semiconductor structure 100 in preparation for deposition of workfunction metals. Subsequently, a metal gate stack 940 and a self-aligned contact cap (hereinafter referred to as “metal cap”) 950 are formed in the semiconductor structure 100. Although not shown in the figures, a gate dielectric stack is typically formed before depositing the metal gate stack 940 and metal cap 950. The gate dielectric stack (not shown) may include, for example, a layer of silicon oxide and a layer of a high-k dielectric material, such as a hafnium based material. The metal gate stack 940 may include one or more work function metals such as, but not limited to, titanium nitride (TiN), tantalum nitride (TaN), titanium carbide (TiC), titanium aluminum carbide (TiAlC), and conducting metals including, for example, aluminum (Al), tungsten (W) or cobalt (Co). As can be appreciated in FIGS. 9A-9B, the metal gate stack 940 surrounds the semiconductor channel layers 108. The gate cap 950 is subsequently formed above the metal gate stack 940. The material forming the gate cap 950 may fill any remaining opening between the metal gate stack 940 and sidewall spacer 510. The material forming the gate cap 950 may be aluminum oxide (AlOx), although other materials such as silicon nitride (SiN) may also or alternatively be used.

After forming the metal gate stack 940 and the gate cap 950, a chemical mechanical polishing (CMP) may be conducted to remove excess material and polish upper surfaces of the semiconductor structure 100.

It should be noted that the presence of the concave inner spacer 830 curving inward in a direction towards the source/drain regions 910 efficiently protects the source/drain regions 910 during the etching step conducted on the sacrificial semiconductor layers 106 (FIGS. 8-8D), and electrically isolates the metal gate stack 940 from the source/drain regions 910. Accordingly, by forming the inner spacer 830 having a concave shape, indentation and etching of the sacrificial semiconductor layers 106 (FIGS. 8-8D) can be conducted without damaging the source/drain regions 910, thereby improving device performance and reliability.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a plurality of semiconductor layers vertically stacked over a semiconductor substrate, each of the plurality of semiconductor layers defining a channel region of the semiconductor structure;
a source/drain region located on opposite ends of the plurality of semiconductor layers;
a metal gate stack surrounding each of the plurality of semiconductor layers; and
an inner spacer located between each of the plurality of semiconductor layers, the inner spacer having a concave surface curving inward in a direction towards the source/drain region, the inner spacer separating the metal gate stack from the source/drain region.

2. The semiconductor structure of claim 1, further comprising:
a sidewall spacer located along opposite sidewalls of the metal gate stack, wherein a second surface of the inner spacer is in contact with the sidewall spacer.

3. The semiconductor structure of claim 1, wherein the inner spacer having the concave surface comprises opposite outer portions of the inner spacer being wider than a middle portion of the inner spacer.

4. The semiconductor structure of claim 1, wherein the inner spacer has a shape that includes two opposite segments and a vertical segment, the two opposite segments being connected by the vertical segment in the shape of a letter “C”, the two opposite segments having a width that is larger than a width of the vertical segment.

5. The semiconductor structure of claim 1, further comprises:
a portion of the semiconductor substrate below the plurality of semiconductor layers being located between shallow trench isolation regions.

6. The semiconductor structure of claim 1, wherein the concave surface of the inner spacer is relative to an outer surface of the metal gate stack for providing an uniform thickness to the inner spacer and protecting the source/drain region, wherein edges of the plurality of semiconductor layers have a substantially square shape.

7. The semiconductor structure of claim 1, wherein the plurality of semiconductor layers comprises at least one of a nanosheet, a nanowire, and a nano-ellipse.

8. A method of forming a semiconductor structure, comprising:
forming a plurality of semiconductor layers vertically stacked over a semiconductor substrate, each of the plurality of semiconductor layers defining a channel region of the semiconductor structure;
forming a source/drain region located on opposite ends of the plurality of semiconductor layers;
forming a metal gate stack surrounding each of the plurality of semiconductor layers; and
forming an inner spacer located between each of the plurality of semiconductor layers, the inner spacer having a concave surface curving inward in a direction towards the source/drain region, the inner spacer separating the metal gate stack from the source/drain region.

9. The method of claim 8, wherein the inner spacer having the concave surface comprises opposite outer portions of the inner spacer being wider than a middle portion of the inner spacer.

10. The method of claim 8, wherein the inner spacer has a shape that includes two opposite segments and a vertical segment, the two opposite segments being connected by the vertical segment in the shape of a letter “C”, the two opposite segments having a width that is larger than a width of the vertical segment.

11. The method of claim 8, wherein the concave surface of the inner spacer is relative to an outer surface of the metal gate stack for providing an uniform thickness to the inner spacer and protecting the source/drain region, wherein edges of the plurality of semiconductor layers have a substantially square shape.

12. The method of claim 8, wherein the plurality of semiconductor layers comprises at least one of a nanosheet, a nanowire, and a nano-ellipse.

13. The method of claim 8, further comprising:
forming a nanosheet stack on the substrate, the nanosheet stack comprising an alternating sequence of sacrificial semiconductor layers and semiconductor channel layers;
patterning the nanosheet stack to form a nanosheet fin; and
forming a dummy gate on the nanosheet fin.

14. The method of claim 13, further comprising:
etching outer portions of the sacrificial semiconductor layers, wherein etching the outer portions of the sacrificial semiconductor layers forms a first indentation region; and
deposition sacrificial dielectric layer within the first indentation region.

15. The method of claim 14, wherein the sacrificial dielectric layer has good etch selectivity to the sacrificial semiconductor layers and includes at least one of SiO₂, SiBCN, SiCN, SiOCN, Ge, and SiGe.

16. The method of claim 15, further comprising:
conformally depositing a spacer material to form a sidewall spacer along opposite sidewalls of the dummy gate; and
using the sidewall spacer along sidewalls of the dummy gate as a mask, etching the nanosheet fin in a way such that a remaining portion of the nanosheet fin is vertically aligned with the sidewall spacer.

17. The method of claim 14, further comprising:
removing the sacrificial dielectric material; and
etching the outer portions of the sacrificial semiconductor layers, wherein etching the outer portions of the sacrificial semiconductor layers forms a second indentation region.

18. The method of claim 16, further comprising:
forming the inner spacer on opposite sides of the sacrificial semiconductor layers;
epitaxially growing the source/drain regions; and
forming a dielectric layer above the source/drain regions and between portions of the sidewall spacer being adjacent to the source/drain regions.

19. The method of claim 18, further comprising:
removing the dummy gate, wherein removing the dummy gate creates a recess between the sidewall spacer; and
selectively removing the sacrificial semiconductor layers.

20. The method of claim 19, further comprising:
forming the metal gate stack within the recess, the metal gate stack surrounding the plurality of semiconductor layers and being separated from the source/drain regions by the inner spacer.
